(19) United States
(12) Patent Application Publication
(10) Pub. No.: US 2003/0000454 A1
(43) Pub. Date: Jan. 2, 2003

(54) Passivation of HgCdTe junction diode by annealing in Cd/Hg atmosphere

(76) Inventors: Sang-Hee Suh, Seoul (KR); Jin-Sang Kim, Seoul (KR)

Correspondence Address: PENNIE AND EDMONDS, 1155 AVENUE OF THE AMERICAS, NEW YORK, NY, 100362711

(21) Appl. No.: 10/085,153

(22) Filed: Feb. 25, 2002

(30) Foreign Application Priority Data
Jun. 28, 2001 (KR) 2001-37515

(51) Int. Cl. C30B 13/00; C30B 21/04; C30B 28/08

(52) U.S. Cl. 117/40

(57) ABSTRACT

A method makes photodiodes by forming a HgCdTe protective, passivation layer with high Cd composition ratio on a HgCdTe semiconductor made of Group II-VI materials. The passivation layer is formed in a Cd/Hg mixed atmosphere via an annealing process wherein vaporized Cd is diffused onto the HgCdTe surface.

### FIELD OF THE INVENTION

The present invention relates to passivation of junction surfaces of photodiodes used as infrared detectors. More specifically, the invention is a method for passivating junction surfaces of HgCdTe semiconductor junction diodes using an annealing method in a Cd/Hg atmosphere to improve detection characteristics of the photodiodes.

### BACKGROUND OF THE INVENTION

One of the most important steps in fabrication of a semiconductor junction diode is passivation of junction surfaces. Particularly for HgCdTe semiconductors with narrow energy bandgaps used as infrared detectors, surface leakage currents will dominate the photocurrent, resulting in abnormal operation in the detector if appropriate passivation is not performed. Problems which exist in the art include extreme difficulty in carrying out successful passivation in semiconductors having narrow energy bandgaps such as HgCdTe semiconductors.

Various materials such as ZnS, SiO₂, CdS, CdTe etc. have been used for passivation of a HgCdTe semiconductor junction diode. Among them, CdTe is the most frequently used as its chemical composition is similar to the HgCdTe semiconductor and its lattice constant is almost equal to HgCdTe.

Conventional methods include a thermal deposition method, a Molecular Beam Epitaxy (MBE) or a Metal-organic Chemical Vapor Deposition (MOCVD) in order to deposit CdTe as a passivation layer over HgCdTe. As junction interfaces are exposed to air during etching, deposition by such conventional methods may create uncontrollable junction surface contamination by an oxide layer or impurities.

To solve this problem, Cockrum et al. suggested in U.S. Pat. No. 5,880,510 a method of using a passivation layer by diffusing Cd on a junction interface of a HgCdTe junction diode, thereby increasing Cd composition ratio. According to the '510 patent, Cd or CdTe is thermally deposited on a junction interface of a HgCdTe junction diode and then annealed at 400° C. for 4 hours under a saturated Hg atmosphere. Cd from Cd or CdTe deposited by this process is diffused onto HgCdTe and Hg is diffused out of the HgCdTe, which raises the Cd composition ratio at the surface regions of HgCdTe. This is followed by annealing at 250° C. for 4 hours under a saturated Hg atmosphere in order to fill Hg voids generated in the crystal lattice of HgCdTe so that electrical characteristic can be controlled.

Cockrum et al. teach that due to the high Cd composition ratio in surface regions of HgCdTe, electrons and holes are reflected therefrom and are prevented from rejoining together at the surface regions. This method, however, requires additional process for depositing Cd or CdTe to be used as a Cd supplier on the junction interface. Additionally the deposited CdTe layer interferes with the annealing process for filling the Hg voids as Hg is diffused very slowly in the CdTe layer. To accelerate the annealing process, the CdTe layer should be partially removed by etching.

Simplification of the fabrication processes is needed in the art to provide a HgCdTe passivation layer having high Cd composition ratio on its surface without depositing a Cd or CdTe layer. A simplified solution will provide a reliable and cost-effective process for the field.

### SUMMARY OF THE INVENTION

To address the above-noted problems in the art, an objective of the present invention is to provide a method for forming a HgCdTe passivation layer having high Cd composition ratio on a HgCdTe junction diode without depositing a Cd or CdTe layer.

The basis of the present invention was research which found that a HgCdTe passivation layer having high Cd composition ratio in its surface can be formed through an annealing process by creating a Cd—Hg mixed vapor atmosphere and diffusing Cd from the Cd vapor onto HgCdTe surfaces. Consequently, the fabrication process is simplified and an economical, cost-effective passivation is provided.

Accordingly, the present invention provides a method for forming a HgCdTe passivation layer having high Cd composition ratio on a HgCdTe p-n junction diode without depositing Cd or CdTe layer in a HgCdTe semiconductor comprised of Group II-VI material.

In particular, the method for forming the passivation layer on the HgCdTe semiconductor p-n junction diode comprises the steps of:

providing a double layered or a multi-layered HgCdTe semiconductor wafer;

etching the wafer by a photolithographic etching method; and

forming a passivation layer by annealing the etched HgCdTe wafer together with Cd and Hg at a temperature of 250° C.˜400° C. such that vaporized Cd is diffused onto the HgCdTe semiconductor wafer, which makes the Cd composition ratio of a surface region in the wafer higher than that of the inside of the wafer.

In the method for forming the passivation layer according to the present invention, it is preferable that the annealing process for the etched HgCdTe wafer in Cd and Hg atmosphere is conducted in a vacuum-sealed container at temperatures ranging 250° C˜400° C. for 1˜5 hours.

The present invention further provides a method for fabricating a photodiode of an excellent quality by forming a high quality HgCdTe passivation layer having high Cd composition ratio in a HgCdTe semiconductor in accordance with the above method for forming the passivation layer.

The present disclosure provides a unique way of making a HgCdTe having high Cd composition ratio as the passivation layer, by using a method wherein a Cd/Hg mixed vapor atmosphere is formed by an annealing process and Cd from the Cd/Hg mixed vapor is diffused onto a surface of the HgCdTe. This is in contrast to conventional methods which employ Cd or CdTe deposited on a surface of HgCdTe, as a Cd supplier for the passivation layer.

According to the present invention, the Cd composition ratio of an outermost surface of HgCdTe and the thickness of the passivation layer can be controlled by appropriately controlling time and temperature of the annealing process. As a result, the present invention can provide a simplified passivation and photodiode fabricating process that can be controlled with ease and carried out without using high priced equipment or protocol.

### BRIEF DESCRIPTION OF THE DRAWINGS

The novel aspects of the invention will be described in detail with reference to the accompanying drawings.

FIG. 1 is an elevated perspective view of a mesa-type array infrared detector.

FIG. 2 is a cross-sectional view of an infrared detector to which passivation according to the present invention is performed.

FIG. 3 is a schematic representation showing energy bands of a HgCdTe passivation layer having high Cd composition ratio according to the present invention, a HgCdTe absorption layer and a cap layer.

FIGS. 4a-4f illustrate a cross-sectional representation of a fabricating process of a HgCdTe junction diode including the passivation process according to the present invention.

FIG. 5 is a graph showing the Cd composition ratio versus depth after performing an annealing process on a HgCdTe wafer under Cd/Hg atmosphere in accordance with the passivation process of the present invention.

FIG. 6a is a graph showing I-V for a long wavelength HgCdTe diode passivated by conventional thermal deposition of CdTe.

FIG. 6b is a graph showing I-V for a long wavelength HgCdTe diode passivated in accordance with the present invention.

### DESCRIPTION OF PREFERRED EMBODIMENTS

Preferred embodiments of the present invention will be described with reference to the drawings.

In the passivation method according to the present invention, an HgCdTe semiconductor wafer in which a p-n diode junction is formed by various methods, is disposed at one end of a tube, and Cd and Hg are disposed at the other end of the tube. The tube is then vacuum-sealed. The vacuum-sealed tube is heated at temperatures ranging 250° C.˜400° C., preferably 250° C.˜350° C. Hg and Cd are vaporized by this process, thereby forming a Cd/Hg atmosphere inside the vacuum tube. This temperature is kept for some hours and the vaporized Cd is diffused onto the surface of the HgCdTe semiconductor, thereby forming an HgCdTe layer in which the surface has higher Cd composition ratio than that of the inside.

As the energy bandgap of this surface layer is too large for electrons and holes to reach the surface, leakage current which could have occurred by their rejoining at the surface, are prevented. Accordingly, performance of an infrared photodiode can be remarkably improved by employing a layer having high Cd composition ratio formed in accordance with the above process, as the passivation layer.

To describe more detailed features of the present invention, the invention will be exemplified as being applied to a backside illuminated photovoltaic mesa-type HgCdTe infrared detector. However, one skilled in the art will appreciate that the present invention could be just as well applied to a frontside illuminated photovoltaic type HgCdTe infrared detector or a planar-type photovoltaic HgCdTe infrared detector, after having the benefit of this disclosure.

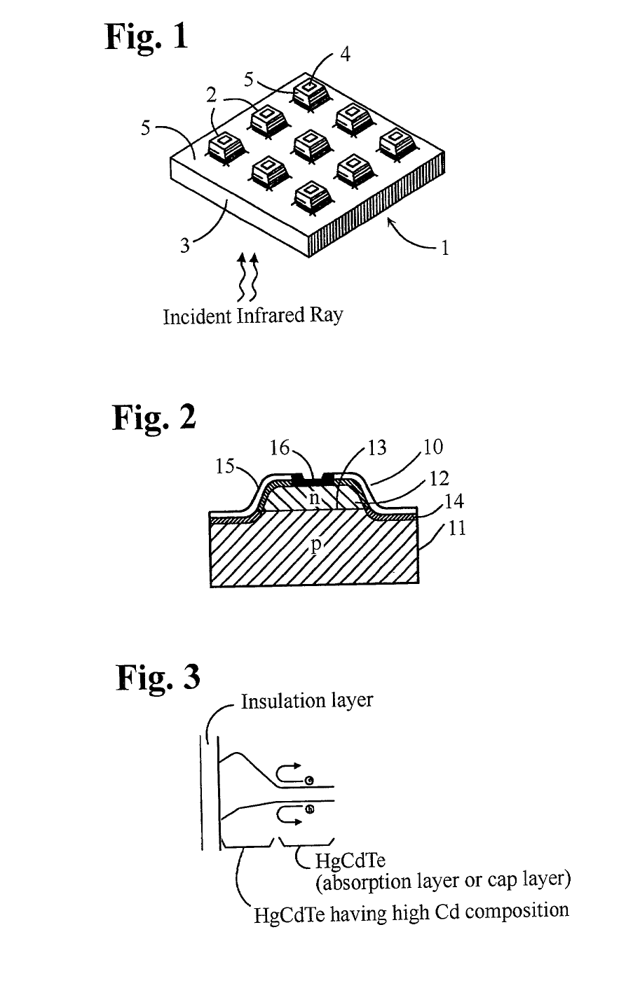

FIG. 1 is a perspective view of an array 1 where photodiodes 2 are regularly arranged in a two-dimensional manner. The photodiodes are made of Hg₍₁₋ₓ₎CdₓTe semiconductor material and junctions of two layers having different conductivity types from each other are formed therein. In the formula, x stands for fraction ratio of Cd in a Cd/Hg mixture.

Liquid Phase Epitaxy (LPE), Molecular Beam Epitaxy (MBE), Metal-Organic Chemical Vapor Deposition (MOCVD) or their equivalents, can be used in fabricating the junctions. The two junction layers are a photo absorption layer and a photo cap layer. The wavelength of infrared ray to be detected by the photodiodes are determined by the composition ratio (x) in Hg₍₁₋ₓ₎CdₓTe of the absorption layer. As illustrated in FIG. 1, an incident infrared ray is illuminated to the backside.

By using an etching, preferably a photolithographic etching method, the HgCdTe wafer is etched down to an upper portion of the photo absorption layer 3 and the respective photodiode devices 2 are isolated from adjacent photodiode devices 2. In other words, a mesa structure is formed by etching. A passivation layer 5 is formed over the mesa structure. Metal contacts 4 are formed on the cap layers of the respective photodiode devices by a thermal deposition method or equivalent resulting in substantially the same effect, which will be used for electrically connecting the photodiode devices to a signal processing circuit via an indium bump.

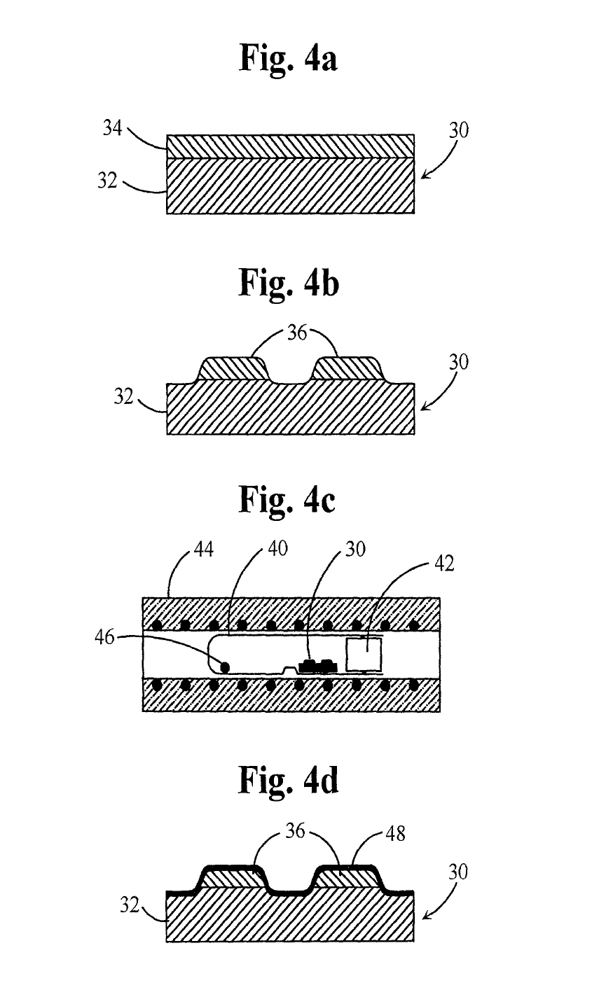

FIG. 2 is a cross-sectional view of a mesa-type array infrared detector of the photodiode device as shown in FIG. 1. The photodiode device 10 has a double-layered structure of homogeneous or heterogeneous p-n junction 13. The photodiode device 10 includes a photo absorption layer 11, and a cap layer 12 whose conductivity type is opposite to the photo absorption layer 11 is deposited thereon to form a p-n junction. A passivation layer 14 and an insulation layer 15 are formed to prevent leakage of current flow from the p-n junction exposed to outside. In the photo absorption layer 11, there are generated electron-hole pairs due to absorption of infrared ray and the generated electron-hole pairs are separated by the p-n junction, which results in photo current flow. The photo current flow is detected by a signal process circuit connected to a metal contact 16 of the photodiode 10.

If the p-n junction exposed to outside by etching, an upper surface of the absorption layer 11, and lateral portions and upper surface of the cap layer 12 are exposed to Cd atmosphere, Cd is diffused into the surface regions thereof so that those surface regions will have HgCdTe structure having high x, i.e. high Cd composition ratio. At interfaces, the crystalline structure of the HgCdTe passivation layer as formed above is continuous with those of the photo absorption layer 11 and the cap layer 12, which are disposed beneath the HgCdTe passivation layer, without any defects.

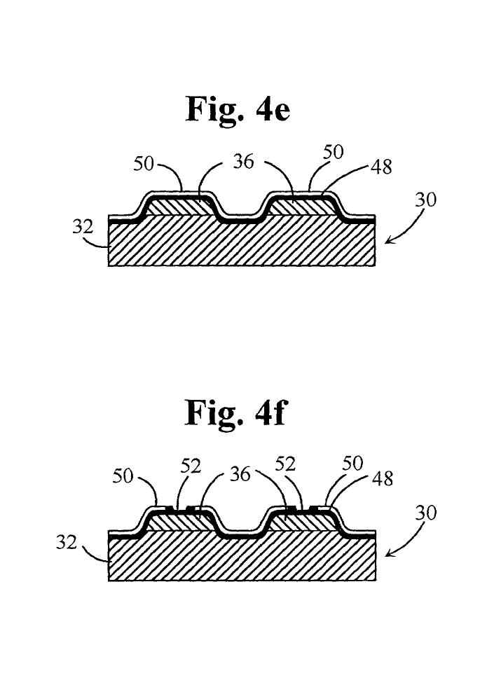

Consequently, structures of the energy bandgap of the photo absorption layer 11 and the cap layer 12 are continuously connected to that of the passivation layer 14 having wider energy bandgap (FIG. 3). Therefore, at an interface with passivation portion, a conduction band is bent upwards and a valence band is bent downwards, electrons and holes are reflected from the interface region to the inside.

The passivation layer 14 acts as a reflecting barrier to both electrons and holes and electrically separates the HgCdTe photodiode device from the surface where impurities and crystalline defects may exist, thereby improving performance of the HgCdTe photodiode device.

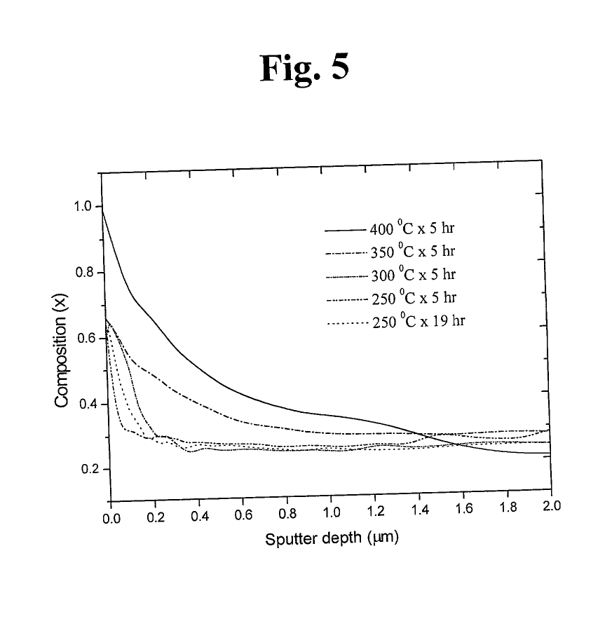

FIGS. 4a to 4f show sequentially the method of forming the HgCdTe passivation layer having high x, i.e. the higher Cd composition ratio in HgCdTe juction diode according to the present invention. Although FIGS. 4a to 4f show the method of forming the HgCdTe passivation layer with regard to the mesa-structured junction diode, it will be clear to those skilled in the art that this method can also be used for a planar-type diode.

FIG. 4a depicts a junction structure of a double layered HgCdTe wafer 30 having an HgCdTe photo absorption layer 32 and an HgCdTe cap layer 34. The photo absorption layer 32 and the cap layer 34 are each doped with an appropriate impurity so that they have different conductivity types.

FIG. 4b depicts a cross-sectional view of the structure of FIG. 4a which is etched to isolate individual diodes 36. The mesa structure is accomplished by a conventional photolithographic etching.

FIG. 4c depicts an annealing process device for diffusing Cd.

Hg and Cd 46 are disposed at the blind end of a tube 40 and an HgCdTe wafer 30 etched in the mesa structure is disposed at the other end of the tube 40. The tube is subject to vacuum evacuation and sealed with a stopper 42. The vacuum tube is then annealed in a furnace 44 which is heated to a temperature of 250° C.˜400° C. for 1˜5 hours. During this step, some of Hg and Cd are vaporized within the vacuum tube 40 and the vaporized Cd diffuses from a surface of the HgCdTe wafer to inside. As time or temperature of the annealing process becomes longer or higher, Cd composition ratio (x) on the HgCdTe surface becomes greater and depth of diffusion becomes deeper. Accordingly, the Cd composition ratio (x) on the HgCdTe surface and the depth of diffusion are controllable by controlling time and temperature of the annealing process.

Thereby, Hg is placed together with Cd so that excessive release of Hg from HgCdTe during annealing can be protected. Although Hg is heated together with Cd in order to prevent the excessive Hg release from HgCdTe, some Hg are diffused out from the surface of the wafer on the annealing process, thereby generating Hg voids in a crystal lattice of the wafer. Accordingly, after the above annealing process, additional annealing is continued under saturated Hg atmosphere at temperature ranging 200° C. ˜280° C. for 2˜20 hours so that the Hg voids are recharged. Hg are relocated to the Hg voids in the crystal lattice of the wafer by this process, however, Cd, which are previously diffused into the wafer, are not released.

FIG. 4d depicts a HgCdTe junction diode wherein Cd is diffused into the HgCdTe by annealing under a Cd atmosphere in accordance with the above method, thereby forming an HgCdTe passivation layer 48 having high Cd composition ratio (x) on the upper surface of the photo absorption layer, the surfaces of the cap layer and the p-n junction, which are exposed to outside.

FIG. 4e depicts a configuration in which an insulation layer 50 is deposited on the upper surface of the individual photodiodes.

FIG. 4f depicts a cross-sectional view of a finished photodiode in which a metal contact 52 is formed by the photolithographic etching.

### EXAMPLE

The following example is provided to illustrate that Cd composition ratio (x) on a surface of an HgCdTe semiconductor can be raised by an annealing process of the present invention.

Referring to FIG. 4c, an HgCdTe wafer having a thickness of 10 μm was formed on a GaAs substrate by the MOCVD method. The Cd composition ratio (x) of the HgCdTe wafer is 0.23. The HgCdTe wafer was etched in a V-shaped mesa structure and introduced into one end of a tube, while Hg and Cd were disposed at the other end of the tube, where the total weight of Hg and Cd is approximately 0.3 g and atomic fraction ratio thereof is 1 versus 1. The samples prepared by the above process were subject to annealing at temperature of 250° C. for 5 hours and 19 hours, and at temperatures of 300° C., 350°C., 400° C. and 450° C. each for 5 hours. Afterwards, all subsequent samples were annealed under an saturated Hg atmosphere at temperature of 250° C. for 6 hours.

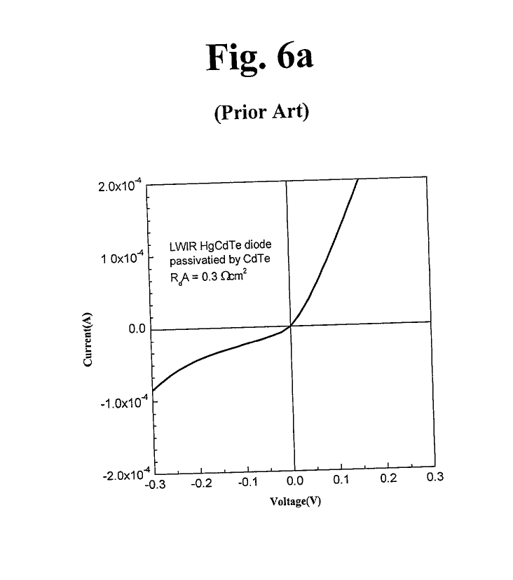

FIG. 5 illustrates the measured results of Cd composition versus depth analyzed by the Auger Electron Spectroscopy (AES) with respect to the annealed HgCdTe wafers by the above conditions.

As shown in FIG. 5, the annealing process performed each at temperatures of 250° C., 300° C. and 350° C. resulted in forming HgCdTe layer of high x value of about x=0.63 at the surface. The thickness of the passivation layer increased with increasing annealing temperature or annealing time. When the annealing process was performed at 400° C. for 5 hours, the surface was almost converted to CdTe with x value of 1.0.

One may expect that the passivation effect will be improved if annealing temperature is high, because a rise of the annealing temperature causes increase of the ratio (x) in the passivation layer. However, as the passivation layer becomes thicker and distribution of doping concentration may be changed due to the high annealing temperature, an appropriate temperature and time for the annealing process is about 250° C.˜350° C. and about 1˜5 hours.

To examine effects of the passivation method according to the present invention on characteristics of the HgCdTe photodiode, the following processes for fabricating a photodiode have been performed.

First, a HgCdTe wafer having a p-n junction etched in the mesa structure was annealed at 260° C. for 5 hours under a Cd/Hg atmosphere, thereby forming a HgCdTe passivation layer having high Cd composition ratio (x). Then, the wafer was annealed again at 250° C. for 6 hours under a saturated Hg atmosphere. As an insulation layer, ZnS having the thickness of 0.6 μm is coated on an upper surface of the wafer and the ZnS layer was punctured for metal contacts by photolithographic etching. By using a thermal deposition method, a metal contact of Au/Ni was formed on a p-type conductivity layer and a metal contact of In was formed on an n-type conductivity layer to form a photodiode.

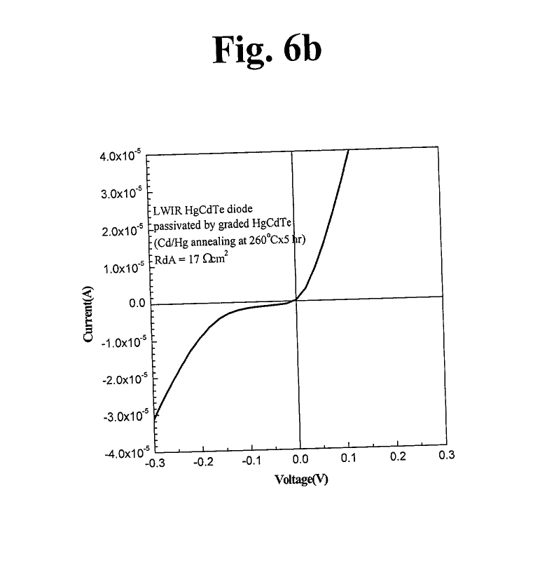

FIGS. 6a and 6b show I-V characteristics for a long wavelength HgCdTe diode passivated by conventional thermal deposition of CdTe, and a diode passivated in accordance with the present invention, respectively.

FIG. 6a illustrates that when a HgCdTe photodiode is passivated by CdTe deposition, the R_{d}A value (dynamic resistance x device area) was created by applying a bias voltage of 50 mV was 0.3Ω-cm². FIG. 6b shows that when a HgCdTe photodiode is passivated according to the present invention, the R_{d}A value of the photodiode passivated was 17Ω-cm². This comparison between the diodes shows that passivation according to the present invention reduces leakage current, resulting in high performance of the diode.

As discussed above, the present invention is able to provide a method for forming a HgCdTe passivation layer having high Cd composition ratio without depositing Cd or CdTe layer, and HgCdTe photodiodes having passivation layers formed according to the present invention exhibit remarkably improved performance.

While the present invention has been described with reference to the above-noted embodiments, it will be apparent to those skilled in the art that adaptations and modifications may be made without departing from the spirit and scope of the invention as defined in the appended claims.

What is claimed is:

1. A method for forming a passivation layer on a HgCdTe semiconductor wafer comprising the steps of:
providing a double layered or a multi layered HgCdTe semiconductor wafer;
etching the wafer by a photolithographic etching method; and
forming a passivation layer by annealing the etched HgCdTe wafer together with Cd and Hg at temperature ranging 250° C.˜400° C. such that vaporized Cd is diffused onto the HgCdTe semiconductor wafer thereby raising the relative Cd composition ratio at the surface region of the wafer to be higher than the inside of the wafer.

2. The method of claim 1, wherein the annealing process on the etched HgCdTe wafer in Cd/Hg atmosphere is performed within a vacuum-sealed container.

3. The method of claim 1 or 2, wherein the annealing process is performed by heating at temperature ranging 250° C.˜350° C. for 1˜5 hours.

4. A method for fabricating a HgCdTe semiconductor junction diode device comprising a step of forming an insulation layer on a passivation layer of a HgCdTe semiconductor wafer, wherein the passivation layer is formed according to the method of claim 1.

5. The method of claim 4, further comprising a step of forming a metal contact on the insulation layer.
